(19) United States
(12) Patent Application Publication
(10) Pub. No.: US 2014/0311552 A1
(43) Pub. Date: Oct. 23, 2014

(54) PHOTOVOLTAIC MODULE MOUNTING AND BONDING CLIP

(71) Applicant: Ben Garrett, Scottsdale, AZ (US)

(72) Inventor: Ben Garrett, Scottsdale, AZ (US)

(21) Appl. No.: 13/864,976

(22) Filed: Apr. 17, 2013

(51) Int. Cl. H01L 31/05; H01R 13/73

(52) U.S. Cl. CPC H01L 31/0508; H01R 13/73
USPC 136/251; 439/386

(57) ABSTRACT

A mounting/bonding clip for use with photovoltaic (PV) modules of the type including an electrically conductive frame and separated by a gap, the clip comprising an electrically conductive body comprising a central portion and first and second spaced-apart arms extending from the central portion. Each arm has first and second outer ends with frame surface-disrupting, electrical contact elements at the outer ends. Each arm extends from the central portion at an obtuse angle to the central portion.

### RELATED APPLICATIONS

This application is related to U.S. Pat. No. 7,780,472, issued on Aug. 24, 2010 and is hereby incorporated herewith.

### BACKGROUND

This invention generally relates to the mounting of framed photovoltaic (PV) modules atop roofs and other support structures, where positive mechanical securement of the modules to the supporting base or structure is desirable and electrical grounding of accessible metal components, such as the PV module frame and ancillary mounting components, is required. Known combined mounting/bonding devices require a special flange on the outside of the photovoltaic module frame and a specially designed clip or other attachment device. Therefore, conventional combined mounting/bonding devices are limited to use with specific module frame geometries.

### SUMMARY

A mounting/bonding clip for use with first and second photovoltaic (PV) modules of the type including an electrically conductive frame and separated by a gap, the clip comprising an electrically conductive body comprising a central portion and first and second spaced-apart arms extending from the central portion, each arm extending from the central portion at an obtuse angle to the central portion. Each arm has first and second outer ends with frame surface-penetrating or surface-disrupting electrical contact element at each outer end. The frame surface-penetrating element points generally towards the plane of the central portion. The frame surface-penetrating element of each arm is orientable in a direction generally perpendicular to the PV module frame. The frame surface-disrupting element may comprise surface-penetrating teeth. The body of the clip is generally U-shaped.

The first and second spaced-apart arms extend from the central portion at an obtuse angle to the central portion. This aspect of the design of the clip provides a wider and more stable mounting application to electrically bond photovoltaic module frames to each other and to a grounded mounting structure, versus prior art clips comprising first and second spaced-apart arms, each extending from the central portion at an acute or right angle to the central portion. As the clip is tightened onto PV module frames, the clip makes contact with the frame and the first and second spaced-apart arms drag inwards, making significantly better bonding contact versus prior art clips.

An example of an electrically conductive mounting/bonding clip assembly, for use with an array of PV modules of the type having electrically conductive frames separated by gaps, includes an electrically conductive clip and a second member. The clip includes a central portion and first and second spaced-apart arms extending from the central portion at an obtuse angle to the central portion. Each arm has first and second outer ends. A frame surface-disrupting element is at each outer end. The central portion defines a plane and the frame surface-disrupting elements point towards the plane. The clip assembly also includes means for (1) biasing the frame surface-disrupting elements of the clip against electrically conductive frames of adjacent PV modules thereby electrically connecting the frames to one another through the clip, and (2) securing the clip to the second member.

An example of a PV installation includes a support, first and second PV modules and an electrically conductive mounting/bonding clip assembly for use with the first and second PV modules. The first and second PV modules are of the type having electrically conductive frames separated by a gap, the frames each having an upper surface. The clip assembly comprises an electrically conductive clip. The clip includes a central portion and first and second spaced-apart, generally T-shaped arms extending from the central portion at an obtuse angle to the central portion. The central portion and arms define an access region accessible from above. Each arm has first and second outer ends. At least one frame surface-disrupting element is at each outer end. The central portion defines a plane. The frame surface-disrupting element points towards the plane. The clip assembly also includes a second member, positioned generally beneath the first and second PV modules and supported by the support, and an elongated connection member. The elongated connection member secures the clip to the second member and is extendable within the gap between the electrically conductive frames so that the frame-disrupting element can be forced against the electrically conductive frames thereby electrically connecting the frames to one another and simultaneously mounting the PV modules to the support through the clip. The central portion includes a hole and the elongated connection member comprises a connection element passing through the hole. The connection element has an upper end located completely within the access region and below the upper surface of the clip. In some examples the frame comprises an electrically non-conductive surface and the frame surface-disrupting portion comprises surface-penetrating teeth. In some examples the connection element may include a threaded member, such as a bolt or a stud.

The features, functions, and advantages may be achieved independently in various embodiments of the disclosure or may be combined in yet other embodiments.

### BRIEF DESCRIPTION OF THE DRAWINGS

Embodiments of the disclosure will become more fully understood from the detailed description and the accompanying drawings, wherein:

FIG. 1 is an exploded view of one embodiment of the clip assembly (ground or roof mounting scenario);

FIG. 2 is an exploded view of one embodiment of the clip assembly (ground or parking canopy mounting scenario);

FIG. 3 is an elevated perspective view of the clip used in the clip assembly of FIG. 1 and FIG. 2;

FIG. 4 is a top view of the clip used in the clip assembly of FIG. 1 and FIG. 2;

FIG. 5 is a side view of the clip used in the clip assembly of FIG. 1 and FIG. 2;

FIG. 6 is a front view of the clip used in the clip assembly of FIG. 1 and FIG. 2; and

FIG. 7 is a simplified diagram showing the grounding of the clip assembly in one embodiment (parking canopy mounting scenario).

### DETAILED DESCRIPTION

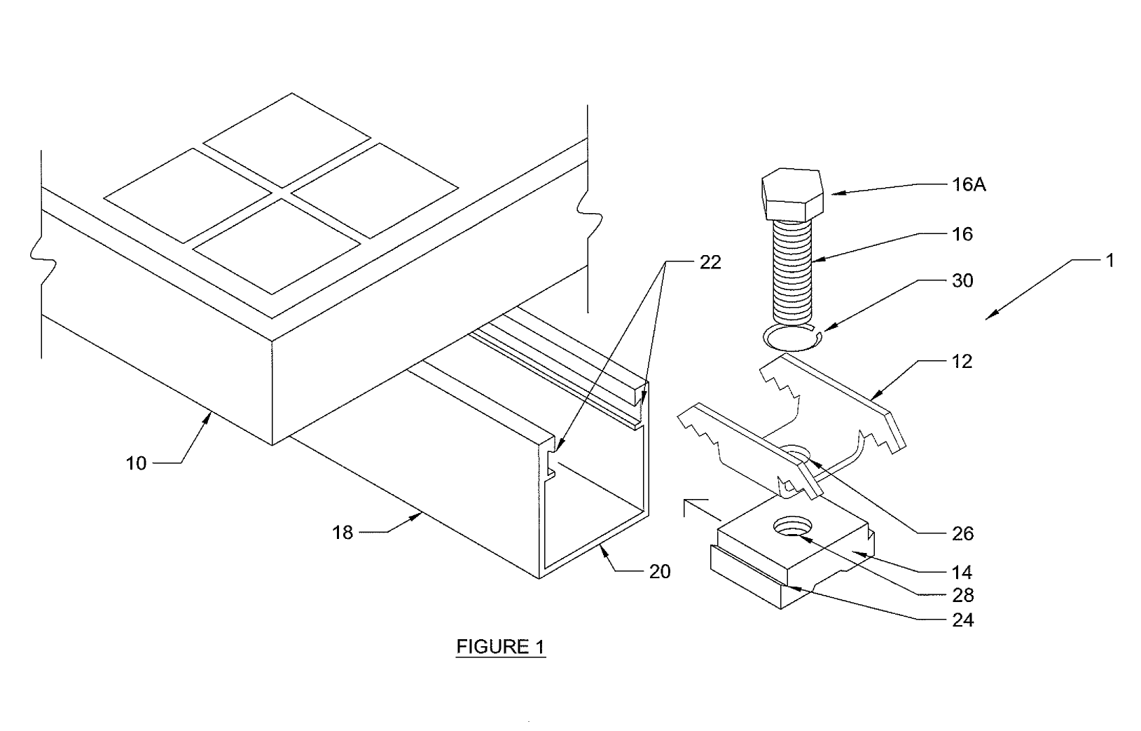

Referring to FIG. 1, an exploded isometric view of a clip assembly 1 (hereinafter Assembly 1) is shown, according to one embodiment of the present invention. The embodiment shown in FIG. 1 relates to a ground or roof mounting scenario. Assembly 1 may be used to secure and electrically bond photovoltaic module frames 10 to each other and to a grounded mounting structure. Assembly 1 may include a clip 12 secured to a channel nut 14 by an elongated connection member 16.

The racking beam 18 may include a base 20, typically of extruded aluminum or some other appropriate material. The racking beam 18 may have a “U” shape frame having a pair of channels 22, with each channel positioned in the top section of each leg of the “U” shape frame.

The channel nut 14 may have a pair of notches 24 formed thereon. In one embodiment, the pair of notches 24 are formed on opposing sides of the channel nut 14. The pair of notches 24 may be formed to allow the channel nut 14 to be positioned within the “U” shape frame of the racking beam 18 by sliding the pair of notches 24 of the channel nut 14 within the pair of channels 22 of the “U” shape frame of the racking beam 18.

Once the channel nut 14 is positioned within the “U” shape frame of the racking beam 18, a securing device in the form of elongated connection member 16 may be used to secure the clip 12 to the racking beam 18. In one embodiment, a bolt 16A may be used. The bolt 16A passes through a central opening 26 in clip 12 and through a hole 28 formed in the channel nut 14. In one embodiment, the central opening 26 in clip 12 may take the shape of a circular hole. The hole 28 may be a threaded hole to secure the bolt 16A to the channel nut 14. A lock washer 30 may be positioned between the clip 12 and the bolt 16A. In accordance with one embodiment, the lock washer 30 may be a circular ring. Thus, the bolt 16A may pass through the lock washer 30, the central opening 26 in clip 12 and through the hole 28 formed in the channel nut 14.

The first and second spaced-apart arms extend from the central portion at an obtuse angle to the central portion. This aspect of the design of the clip 12 provides a wider and more stable mounting application to electrically bond photovoltaic module frames 10 to each other and to a grounded mounting structure, versus prior art clips comprising first and second spaced-apart arms, each extending from the central portion at an acute or right angle to the central portion. As the clip 12 is tightened onto the photovoltaic module frame 10, the clip 12 makes contact with the frame 10 and the first and second spaced-apart arms drag inwards, making significantly better bonding contact versus prior art clips.

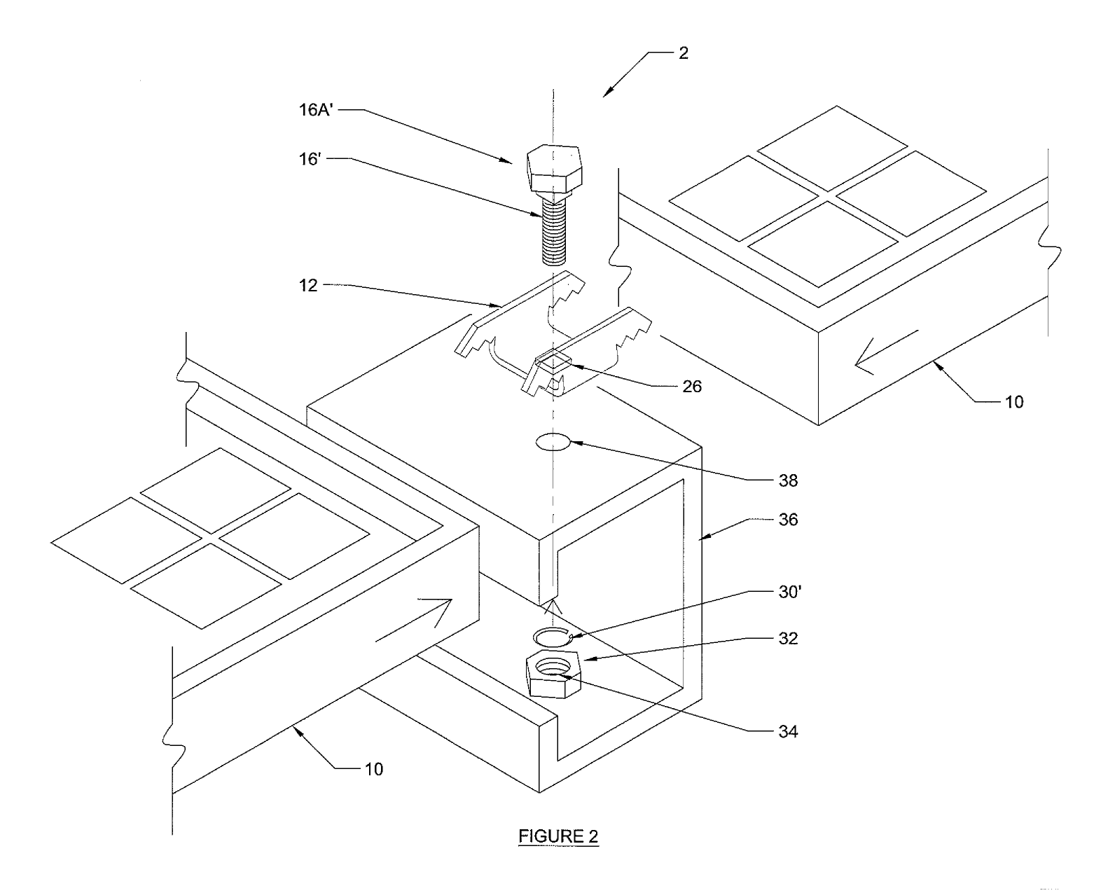

Referring now to FIG. 2, an exploded isometric view of a clip assembly 2 (hereinafter Assembly 2) is shown, according to one embodiment of the present invention. The embodiment shown in FIG. 2 relates to a ground or parking canopy mounting scenario. Assembly 2 is similar to Assembly 1 depicted in FIG. 1. In this embodiment, the Assembly 2 may be used to secure and electrically bond photovoltaic modules 10 to each other and to a grounded mounting structure. Assembly 2 may include a clip 12 secured to a hex nut 32 by an elongated connection member 16′. In the present embodiment, a bolt 16A′ may be used.

A support structure 36 used to mount the photovoltaic modules 10 must include a hole 38. The support structure 36 may take the form of a C-, Z-, or L-shaped purlin, typically of steel or some other appropriate material.

The bolt 16A′ passes through a central opening 26 in clip 12, through hole 38 in support structure 36 and finally through a hole 34 formed in the hex nut 32. In one embodiment, the central opening 26 in clip 12 may take the shape of a square hole. The hole 34 may be a threaded hole to secure the bolt 16A′ to the hex nut 32. A lock washer 30′ may be positioned between the hole 38 in support structure 36 and the hex nut 32. In accordance with one embodiment, the lock washer 30′ may be a circular ring. Thus, the bolt 16A′ may pass through the central opening 26 in clip 12, the hole 38 in the support structure 36, the lock washer 30′ and finally through the hole 34 formed in the hex nut 32.

The first and second spaced-apart arms extend from the central portion at an obtuse angle to the central portion. This aspect of the design of the clip 12 provides a wider and more stable mounting application to electrically bond photovoltaic module frames 10 to each other and to a grounded mounting structure, versus prior art clips comprising first and second spaced-apart arms, each extending from the central portion at an acute or right angle to the central portion. As the clip 12 is tightened onto the photovoltaic module frame 10, the clip 12 makes contact with the frame 10 and the first and second spaced-apart arms drag inwards, making significantly better bonding contact versus prior art clips.

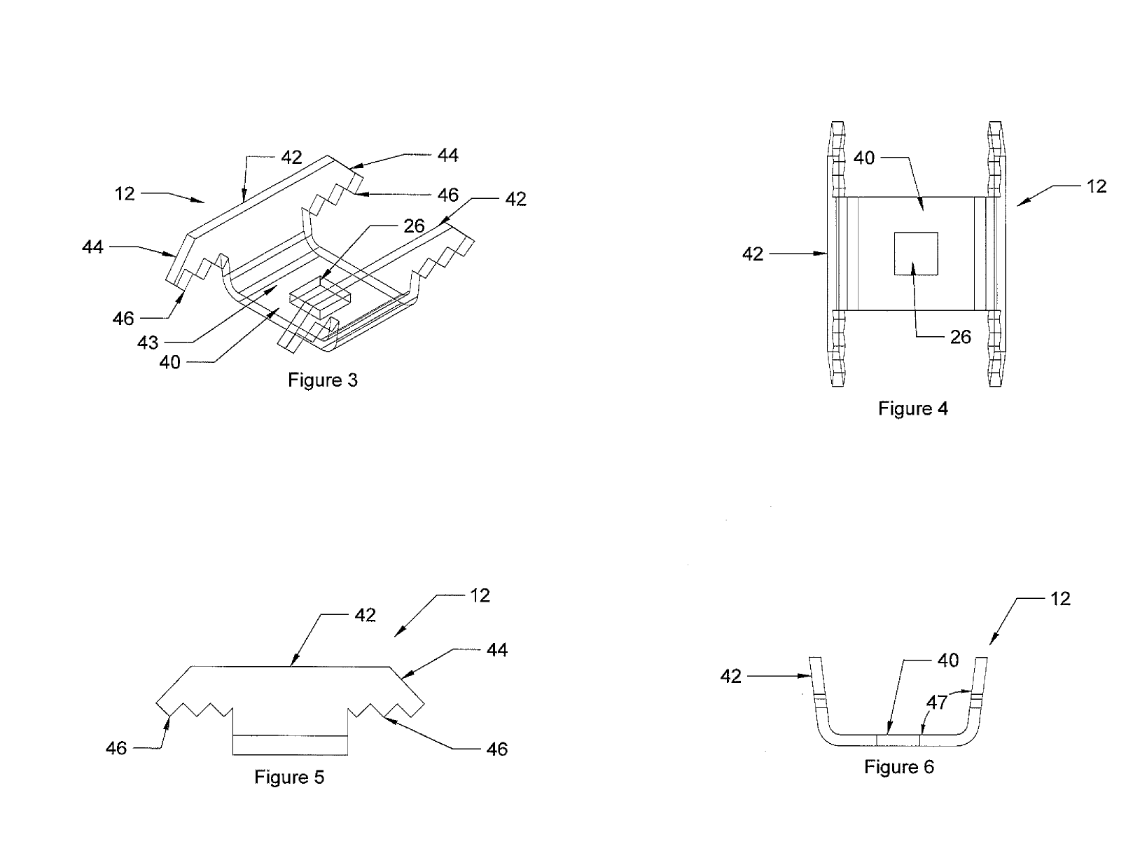

Referring now to FIGS. 3-6, the clip 12 of FIGS. 1-2 are shown in more detail. The clip 12 is a generally U-shaped structure having a central portion 40, through which central opening 26 is formed, and a pair of upstanding arms 42. Arms 42 and central portion 40 define an access region 43. Access region 43 is accessible from above to provide clear access to elongated connection member 16 thus facilitating the use of clip assemblies 1 and 2. Arms 42 include outer ends 44 having downwardly extending teeth 46.

In the embodiment shown in FIGS. 3-6, three teeth 46 are used at each extension 44 of arms 42. However, this is shown as an example and should not be seen in a limiting manner. The use of a number of points 46 at each extension 44 allows some adjustment in the position of clip 12 relative to the photovoltaic module frames 10, thus facilitating installation. Teeth 46 are oriented to be generally perpendicular to the adjacent photovoltaic module frames 10.

Arms 42 are preferably not perpendicular to central portion 40. In the disclosed example, arms 42 extend outwardly over central portion 40 to define an included angle 47. Included angle 47 is an obtuse angle. In the embodiment shown in FIG. 6, the included angle 47 is approximately 97°. The benefit of the obtuse angle versus an acute or right angle is as follows: the obtuse angle provides a wider gripping area and therefore a more stable mounting application to electrically bond photovoltaic module frames 10 to each other and to a grounded mounting structure. As the clip 12 is tightened onto the photovoltaic module frame 10, the clip 12 makes contact with the frame and the first and second spaced-apart arms drag inwards, making significantly better bonding contact versus prior art clips which utilize acute or right angles. Arms extending outwardly over the central portion at acute or right angles do not drag inwards as the clip is secured and tightened to a grounded mounting structure.

Due to the vertical contact with the photovoltaic module frames 10, a downward application of force from the positively attached bolt 16A/16A′ on the central portion 40 of the clip 12 results in horizontal motion of the arms 42 and outer ends 44 in the direction of the central portion 40. This translational motion is resisted by the module frame 10 whereby the friction between the clip 12 and frame 10 results in the teeth 46 gouging the anodized non-conductive surface of the frame 10, thus exposing the conductive material beneath. This result is best achieved when included angle 47 is an obtuse angle.

In operation, as shown in FIGS. 1-2, the head of bolt 16A/16A′ is located completely within access region 43 and is located below the top surface of the clip 12. In addition, the generally T-shaped configuration of arms 42 with downwardly facing teeth 46 provide for a low profile structure. This low profile structure creates a cleaner, less cluttered appearance and also minimizes potential shading by the clip 12 of the photovoltaic modules.

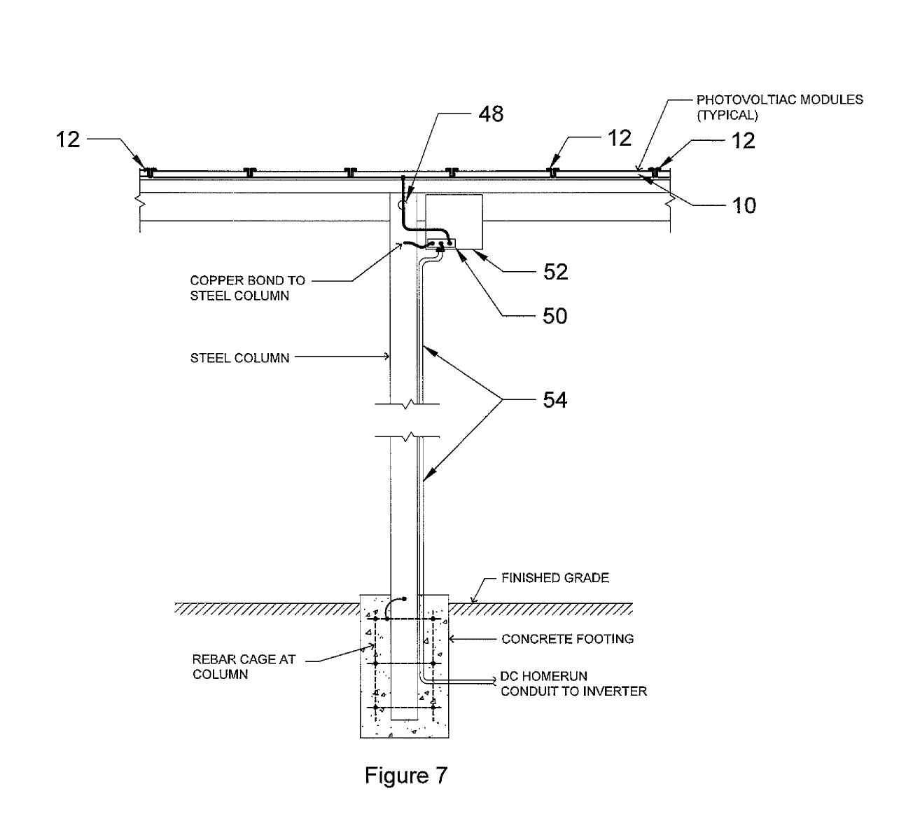

Referring to FIG. 7, which depicts a parking canopy mounting scenario consistent with Assembly 2 shown in FIG. 2, the teeth 46 may be used as surface-disrupting elements to ensure electrical contact between the clip 12 and the photovoltaic module frame 10. The serrated teeth 46 may cut through any nonconductive material on the frame 10, thereby creating a positive electrical connection. This electrical contact on both outer ends 44 of each arm 42, helps to ensure electrical bonding between adjacent PV modules through clip 12. As shown in FIG. 7, since the clip 12 may ensure good electrical contact/continuity between adjacent module frames 10, a single grounding wire 48 may be used. The grounding wire 48 may be attached to the frame 10 and then to a ground bus 50. In the present embodiment, the ground bus 50 may be located within a DC combiner box 52. A wire 54 may run from the ground bus 50 to ground potential.

While embodiments of the disclosure have been described in terms of various specific embodiments, those skilled in the art will recognize that the embodiments of the disclosure may be practiced with modifications within the spirit and scope of the claims.

What is claimed is:

1. A clip for use with first and second photovoltaic (PV) modules of the type including an electrically conductive frame and separated by a gap, the clip comprising:
an electrically conductive body comprising a central portion and first and second spaced-apart arms extending from the central portion;
wherein each arm having first and second outer ends with frame surface-disrupting, electrical contact element at the outer ends, and each arm extending from the central portion at an obtuse angle to the central portion.

2. The clip according to claim 1, further comprising a plurality of said frame surface-disrupting elements at each outer end.

3. The clip according to claim 1, wherein the frame surface-disrupting element comprises surface-penetrating teeth.

4. The clip according to claim 1, wherein the body is generally U-shaped.

5. The clip according to claim 1, wherein the body comprises two arms and two outer ends for each arm.

6. The clip according to claim 1, wherein: the central portion and the first and second arms define a generally U-shaped path; and the outer ends extend in directions generally perpendicular to the generally U-shaped path.

7. The clip according to claim 1, wherein said first and second arms define first and second arm planes, respectively, the outer ends of said first arm lying in the first arm plane and the outer ends of said second arm lying in the second arm plane.

8. The clip according to claim 1, further comprising:
a second member; and
an elongated connection element securing the clip to the second member so that the frame surface-disrupting element can be forced against PV modules thereby electrically connecting the PV modules to one another and simultaneously mounting the PV modules to a support through the clip.

9. The clip according to claim 8, wherein the central portion comprises an opening and the elongated connection element passes through the opening, the connection element having an upper end, the upper end located completely between the first and second arms of the clip.

10. A clip for use with first and second photovoltaic (PV) modules of the type including an electrically conductive frame and separated by a gap, the clip comprising:
an electrically conductive body comprising a central portion and first and second spaced-apart arms extending from the central portion, each arm extending from the central portion at an obtuse angle to the central portion;
each arm having first and second outer ends with frame surface-penetrating, electrical contact elements at each outer end, the frame surface-penetrating elements pointing generally towards the plane of the central portion; and
the frame surface-penetrating elements of each arm being orientable in a direction generally perpendicular to the PV module frame.

11. The clip according to claim 10, wherein the frame surface-disrupting elements comprise surface-penetrating teeth.

12. The clip according to claim 10, wherein the central portion and the first and second arms define a generally U-shaped path, and the outer ends extend in directions generally perpendicular to the generally U-shaped path.

13. The clip according to claim 10, further comprising:
a second member; and
an elongated connection element securing the clip to the second member so that the frame surface-disrupting element can be forced against PV modules thereby electrically connecting the PV modules to one another and simultaneously mounting the PV modules to a support through the clip.

14. The clip according to claim 13, wherein the central portion comprises an opening and the elongated connection element passes through the opening, the connection element having an upper end, the upper end located completely between the first and second arms of the clip.

15. A clip for use with first and second photovoltaic (PV) modules of the type including an electrically conductive frame and separated by a gap, the clip comprising:
an electrically conductive body comprising a central portion and first and second spaced-apart arms extending from the central portion;
wherein each arm having first and second outer ends with frame surface-disrupting, electrical contact element at the outer ends, and each arm extending from the central portion at an obtuse angle to the central portion;
wherein the frame surface-disrupting element comprises surface-penetrating teeth;
wherein the body is generally U-shaped.

16. The clip according to claim 15, wherein said first and second arms define first and second arm planes, respectively, the outer ends of said first arm lying in the first arm plane and the outer ends of said second arm lying in the second arm plane.

17. The clip according to claim 15, further comprising:
a second member; and
an elongated connection element securing the clip to the second member so that the frame surface-disrupting element can be forced against PV modules thereby electrically connecting the PV modules to one another and simultaneously mounting the PV modules to a support through the clip.

18. The clip according to claim 17, wherein the central portion comprises an opening and the elongated connection element passes through the opening, the connection element having an upper end, the upper end located completely between the first and second arms of the clip.

19. A photovoltaic installation comprising a support; first and second PV modules of the type having electrically conductive frames separated by a gap, the frames each having an upper surface; and
A clip assembly for use with the first and second .PV modules, the clip assembly comprising:
an electrically conductive body comprising a central portion and first and second spaced-apart arms extending from the central portion;
each arm extending from the central portion at an obtuse angle to the central portion;
each arm having first and second outer ends with frame surface-disrupting, electrical contact elements at the outer ends.
a generally U-shaped body; and
the first and second arms define first and second arm planes, respectively, the outer ends of said first arm lying in the first arm plane and the outer ends of said second arm lying in the second arm plane.

20. The photovoltaic (PV) installation according to claim 19, further comprising:
a second member; and
an elongated connection element securing the clip to the second member so that the frame surface-disrupting element can be forced against PV modules thereby electrically connecting the PV modules to one another and simultaneously mounting the PV modules to the support through the clip.

21. The photovoltaic (PV) installation according to claim 20, wherein the central portion comprises an opening and the elongated connection element passes through the opening, the connection element having an upper end, the upper end located completely between the first and second arms of the clip.
